(19) United States
(12) Patent Application Publication
(10) Pub. No.: US 2026/0075808 A1
(43) Pub. Date: Mar. 12, 2026

(54) SEMICONDUCTOR DEVICE AND MANUFACTURING METHOD THEREFOR

(71) Applicant: CXMT Corporation, Hefei (CN)

(72) Inventors: Daohuan FENG, Hefei (CN); YU-CHENG LIAO, Hefei (CN); Yi JIANG, Hefei (CN); Wenli ZHAO, Hefei (CN); Minrui HU, Hefei (CN); Chen YANG, Hefei (CN)

(21) Appl. No.: 19/392,143

(22) Filed: Nov. 18, 2025

Related U.S. Application Data
(63) Continuation of application No. PCT/CN2024/089455, filed on Apr. 24, 2024.

(30) Foreign Application Priority Data
Jun. 12, 2023 (CN) 202310699691.8

(51) Int. Cl. H10B 12/00

(52) U.S. Cl. CPC H10B 12/482; H10B 12/02; H10B 12/315

(57) ABSTRACT

Provided are a semiconductor device and a manufacturing method therefor. The semiconductor device includes: a substrate; active strips and first trenches located on a surface of the substrate, extending along a first direction, and alternately arranged along a second direction, and a plurality of active pillars located on surfaces of the active strips and spaced apart along the first direction; a first isolation layer extending along the first direction and located at a bottom of each first trench; a bit line structure located on a top surface of the first isolation layer and covering part of a side wall of one of the active strips; a first isolation structure located between adjacent bit line structures in the first trench; and an air gap located in the first isolation structure.

### CROSS-REFERENCE

This application is a continuation of International Patent Application No. PCT/CN2024/089455, filed on Apr. 24, 2024, which claims the benefit of Chinese Patent Application No. 202310699691.8, titled “SEMICONDUCTOR DEVICE AND MANUFACTURING METHOD THEREFOR”, filed with the China National Intellectual Property Administration (CNIPA) on Jun. 12, 2023, the disclosures of which are incorporated herein by reference in their entireties.

### TECHNICAL FIELD

The present application relates to the technical field of semiconductors, and relates to, but is not limited to, a semiconductor device and a manufacturing method therefor.

### BACKGROUND

Currently, a dynamic random access memory (dynamic random access memory, DRAM) provided with a buried bit line structure is formed, to improve the integration level of the DRAM and achieve miniaturization.

However, the coupling between buried bit line structures in the related art is relatively severe, and the parasitic capacitance is large, which affects the sensing margin of the sense amplifier (sense amplifier, SA). In addition, the current leakage in the buried bit line structure in the related art is relatively severe, which affects the working performance of the DRAM.

### SUMMARY

In view of this, embodiments of the present application provide a semiconductor device and a manufacturing method therefor.

In a first aspect, the embodiments of the present application provide a semiconductor device. The semiconductor device includes:
a substrate;
active strips and first trenches located on a surface of the substrate, extending along a first direction, and alternately arranged along a second direction, and a plurality of active pillars located on surfaces of the active strips and spaced apart along the first direction;
a first isolation layer extending along the first direction and located at a bottom of each of the first trenches;
a bit line structure located on a top surface of the first isolation layer and covering part of a side wall of one of the active strips;
a first isolation structure located between adjacent bit line structures in the first trench; and
an air gap located in the first isolation structure, wherein
the first direction intersects with the second direction and is located in a plane where the substrate is located.

In a second aspect, the embodiments of the present application provide a method for manufacturing a semiconductor device. The method includes:
providing a base substrate, where the base substrate includes initial active strips and first trenches extending along a first direction and alternately arranged along a second direction;
forming a first isolation layer extending along the first direction at a bottom of each first trench;
forming a bit line structure on a top surface of the first isolation layer and part of an inner wall of the first trench, where a gap is provided between two adjacent bit line structures located in a same first trench; and
forming a first isolation structure in the gap and an air gap located in the first isolation structure, wherein
the first direction intersects with the second direction and is located in a plane where the base substrate is located.

### BRIEF DESCRIPTION OF DRAWINGS

In the drawings (may not necessarily be drawn to scale), similar reference numerals may describe similar components in different views. Similar reference numerals with different suffix letters may represent similar components in different examples. The drawings show generally, by way of example without limitation, various embodiments discussed herein.

FIG. 1 is a schematic flowchart of a method for manufacturing a semiconductor device according to the embodiments of the present application; and

FIGS. 2 to 21 are schematic structural diagrams illustrating a process of forming a semiconductor device according to the embodiments of the present application.

### DESCRIPTION OF EMBODIMENTS

Exemplary embodiments disclosed in the present application will be described in more detail below with reference to the drawings. While exemplary embodiments of the present application are shown in the drawings, it should be understood that the present application may be implemented in various forms and should not be limited by the specific embodiments set forth herein. Rather, these embodiments are provided so that the present application will be more thoroughly understood and the scope disclosed in the present application will be fully conveyed to those skilled in the art.

In the following descriptions, many details are provided for a more thorough understanding of the present application. However, it is apparent to those skilled in the art that the present application can be implemented without one or more of these details. In other instances, some well-known technical features in the art are not described to avoid confusion with the present application; i.e., not all features of the actual embodiments are described herein, and well-known functions and structures are not described in detail.

In the drawings, the dimensions of layers, regions, and elements, and their relative dimensions may be exaggerated for clarity. Identical reference numerals represent identical elements throughout the text.

It should be understood that when an element or layer is referred to as being “on”, “adjacent to”, “connected to”, or “coupled to” another element or layer, the element or layer may be directly on, adjacent to, connected to, or coupled to the another element or layer, or there may be an element or layer in between. On the contrary, when an element is referred to as being “directly on”, “directly adjacent to”, “directly connected to”, or “directly coupled to” another element or layer, there is no element or layer in between. It should be appreciated that, although the terms first, second, third, etc., may be used to describe various elements, components, regions, layers, and/or parts, the elements, components, regions, layers, and/or parts should not be limited by these terms. These terms are only used to distinguish one element, component, region, layer, or part from another element, component, region, layer, or part. Therefore, a first element, component, region, layer, or part discussed below may be termed a second element, component, region, layer, or part without departing from the teachings of the present application. However, the discussion of a second element, component, region, layer, or part does not necessarily imply that a first element, component, region, layer, or part is necessarily present in the present application.

The terms used herein are for the purpose of describing specific embodiments only and should not be construed as limiting the present application. As used herein, the singular forms “a”, “an”, and “the” are intended to include the plural forms as well, unless the context clearly indicates otherwise. It should be further understood that the terms “comprise” and/or “include”, when used in this specification, specify the presence of stated features, integers, steps, operations, elements, and/or components, but do not exclude the presence or addition of one or more other features, integers, steps, operations, elements, components, and/or groups. As used herein, the term “and/or” includes any and all combinations of the associated listed items.

Currently, the coupling between buried bit line structures is relatively severe, and the parasitic capacitance is large, which affects the sensing margin of the sense amplifier. In addition, the current leakage between the buried bit line structure and the substrate is relatively severe, which affects the working performance of the semiconductor device.

Based on this, the embodiments of the present application provide a semiconductor device and a manufacturing method therefor. The semiconductor device includes: a base substrate, including active strips and first trenches extending along a first direction and alternately arranged along a second direction, and a plurality of active pillars located on the surfaces of the active strips and spaced apart along the first direction; a first isolation layer extending along the first direction and located at the bottom of each first trench; a bit line structure located on the top surface of the first isolation layer and covering the side wall of one of the active strips; a first isolation structure located between adjacent bit line structures in the first trench; and an air gap located in the first isolation structure. Since the air gap is formed in the first isolation structure between the bit line structures, the coupling effect between adjacent bit line structures can be reduced, and the parasitic capacitance can be reduced, thereby improving the sensing margin of the sense amplifier. In addition, since the first isolation layer is formed at the bottom of the bit line structure, the current leakage between the bit line structure and the base substrate can be prevented, thereby improving the electrical performance of the semiconductor device.

A semiconductor device and a manufacturing method therefor in the embodiments of the present application are described in detail below with reference to the drawings.

Before describing the embodiments of the present application, three directions for describing a three-dimensional structure that may be used in the following embodiments are defined. Taking the Cartesian coordinate system as an example, the three directions may include the X-axis, Y-axis, and Z-axis directions. The thickness direction of the base substrate is defined as a third direction. In the direction of a plane where the base substrate is located, two intersecting directions (for example, perpendicular to each other) are defined as a second direction and a third direction. For example, the arrangement direction of the active strips and the first trenches may be defined as the second direction. Here, the first direction may be, for example, the X-axis direction, the second direction may be, for example, the Y-axis direction, and the third direction may be, for example, the Z-axis direction.

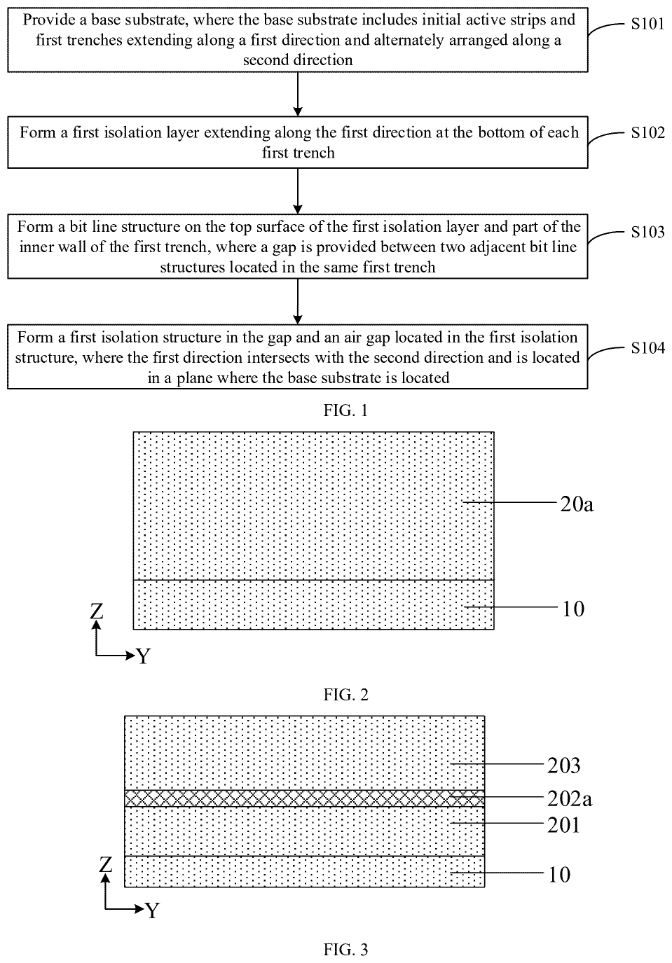

FIG. 1 is a schematic flowchart of a method for manufacturing a semiconductor device according to the embodiments of the present application. FIGS. 1 to 21 are schematic structural diagrams illustrating a process of manufacturing a semiconductor device according to the embodiments of the present application. The process of forming a semiconductor device is described in detail below with reference to FIGS. 1 to 21.

As shown in FIG. 1, the method for manufacturing a semiconductor device includes the following steps S101 to S104.

First, referring to FIGS. 1 to 7, step S101 is performed to provide a base substrate. The base substrate includes initial active strips 20b and first trenches 12 extending along the first direction and alternately arranged along the second direction.

It should be noted that the initial active strips 20b are used to form source regions, drain regions, and channel regions of transistors in the semiconductor device, and bit line structures and word line structures of the semiconductor device are formed in the first trenches 12.

In some embodiments, providing the base substrate includes the following steps.

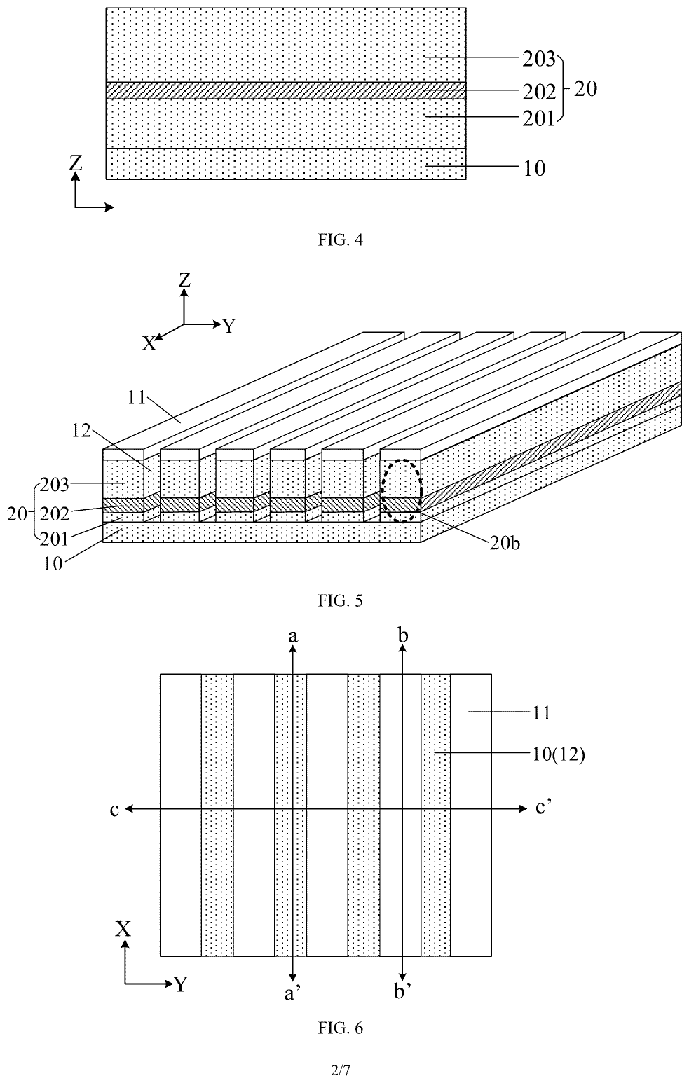

In step one, a substrate 10 and a semiconductor layer 20 as shown in FIG. 4 are provided. The semiconductor layer 20 includes a first semiconductor layer 201, a first insulating layer 202, and a second semiconductor layer 203 sequentially stacked along the third direction.

Here, the substrate 10 may be a silicon substrate, and the substrate 10 may further include other semiconductor elements such as germanium (Ge); or include semiconductor compounds such as silicon carbide (SiC), gallium arsenide (GaAs), gallium phosphide (GaP), indium phosphide (InP), indium arsenide (InAs), or indium antimonide (InSb); or include other semiconductor alloys such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide phosphide (GaInAsP), or a combination thereof.

The main body material layer of the semiconductor layer 20 may be made of the same material as the substrate 10, or may be a silicon wafer after surface treatment (i.e., a monocrystalline silicon material layer), or may be a material layer including other semiconductor elements such as polycrystalline silicon.

In some embodiments, the semiconductor layer 20 may be formed by using the SIMOX technology. Specifically, providing the semiconductor layer 20 may include the following steps.

In step 1, an initial semiconductor structure 20a as shown in FIG. 2 is provided.

In step 2, oxygen ion implantation is performed on the initial semiconductor structure 20a to form a buried layer 202a located inside the initial semiconductor structure 20a as shown in FIG. 3.

It should be noted that the buried layer 202a is a layer doped with high-dose oxygen ions inside the initial semiconductor structure 20a, and the high-dose oxygen ions may be implanted at a high temperature.

In step 3, the initial semiconductor structure 20a and the buried layer 202a are annealed to form a first insulating layer 202, where the material of the first insulating layer 202 includes silicon dioxide, the initial semiconductor structure 20a located below the first insulating layer 202 constitutes the first semiconductor layer 201, and the initial semiconductor structure 20a located above the first insulating layer 202 constitutes the second semiconductor layer 203.

It should be noted that the semiconductor layer 20 constituted by the second semiconductor layer 203, the first insulating layer 202, and the first semiconductor layer 201 may be understood as a silicon-on-insulator (silicon-on-insulator, SOI) wafer on an insulating substrate. The first semiconductor layer 201 is equivalent to a bulk silicon in the SOI wafer, the first insulating layer 202 is equivalent to a silicon dioxide buried layer in the SOI wafer, and the second semiconductor layer 203 is equivalent to a top silicon layer in the SOI wafer.

It should be further noted that the first semiconductor layer 201 and the substrate 10 may be made of the same material, thereby forming a continuous layer.

In other embodiments, the semiconductor layer 20 may also be formed by the following steps:
depositing a semiconductor material on the surface of the substrate 10 to form a first initial semiconductor layer, where the semiconductor material includes a polycrystalline semiconductor material;
depositing an insulating material on the surface of the first semiconductor layer 201 to form a first insulating layer 202, where the insulating material may be silicon dioxide;
depositing a semiconductor material again on the surface of the first insulating layer 202 to form a second initial semiconductor layer; and
performing high-temperature heat treatment on the first initial semiconductor layer and the second initial semiconductor layer to form the first semiconductor layer 201 and the second semiconductor layer 203.

It should be noted that the first initial semiconductor layer and the second initial semiconductor layer formed by deposition are polycrystalline semiconductor materials, and the polycrystalline semiconductor materials can be converted into monocrystalline semiconductor materials by high-temperature heat treatment. In this way, the mobility of carriers in the channel structure can be improved, thereby improving the drive current of the formed transistor, and further improving the response speed of the semiconductor device.

It should be further noted that the polycrystalline semiconductor material may include polycrystalline silicon, polycrystalline germanium, or polycrystalline silicon germanium.

The semiconductor layer 20 is patterned until the substrate 10 is exposed to form initial active strips 20b and first trenches 12, where the initial active strips 20b include a first semiconductor layer 201, a first insulating layer 202, and a second semiconductor layer 203 sequentially stacked along the third direction.

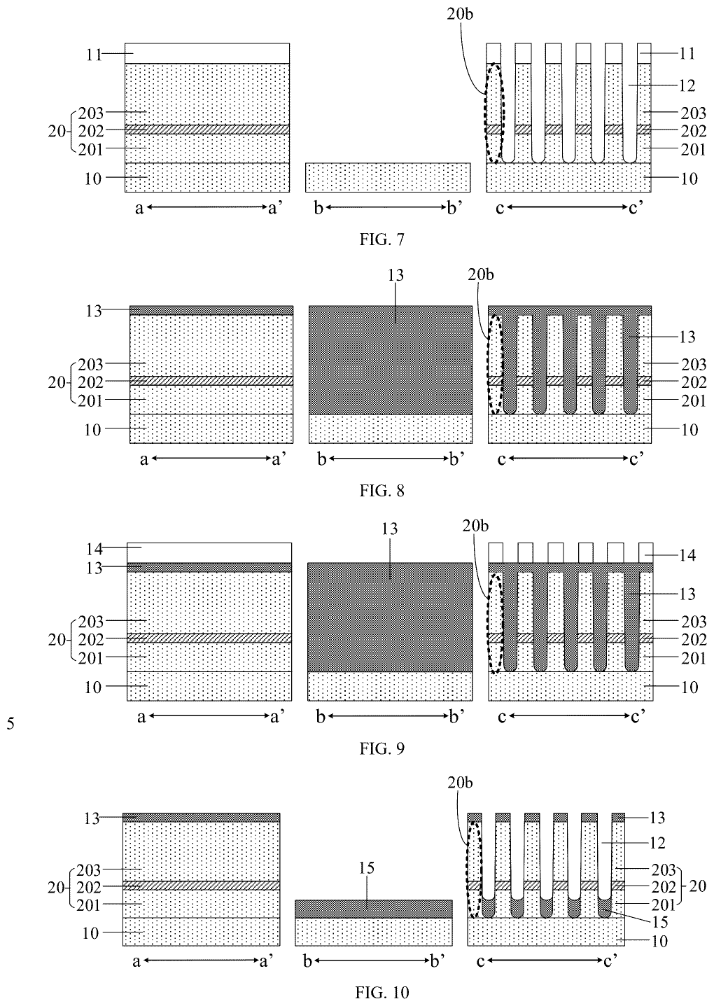

During implementation, for example, first photoresist layers 11 having a preset pattern as shown in FIGS. 5 to 7 may be formed on the surface of the semiconductor layer 20, where the preset pattern includes a plurality of sub-patterns spaced apart from each other along the Y-axis direction, and each sub-pattern extends along the X-axis direction and exposes part of the semiconductor layer 20. Next, the semiconductor layer 20 is etched through the first photoresist layer 11, and the part of the semiconductor layer 20 exposed by each sub-pattern is removed to form the initial active strips 20b and the first trenches 12 located between the initial active strips 20b as shown in FIGS. 5 and 7. The bottom of each first trench 12 exposes the substrate 10.

It should be noted that FIG. 5 is a three-dimensional view of the semiconductor device, FIG. 6 is a top view of FIG. 5, and FIGS. 7 to 19 are cross-sectional views along a-a′, b-b′, and c-c′ in FIG. 6, which will not be described in detail subsequently.

It should be further noted that since the initial active strips 20b are formed by patterning the semiconductor layer 20, when the main body material of the semiconductor layer 20 is monocrystalline silicon, since monocrystalline silicon has high electron mobility, the use of monocrystalline silicon as the channel structure can increase the mobility of the carriers in the channel structure, thereby improving the drive current of the formed transistor, and further improving the response speed of the semiconductor device.

Next, with continued reference to FIG. 1, and 8 to 10, step S102 is performed to form a first isolation layer 15 extending along the first direction at the bottom of the first trench 12.

It should be noted that the first isolation layer 15 is located at the bottom of the first trench 12, and a bit line structure is subsequently formed on the surface of the first isolation layer 15 in the first trench 12. The first isolation layer 15 is located between the bit line structure and the substrate 10, such that current leakage from the bit line structure to the substrate 10 can be prevented, thereby improving the electrical performance of the semiconductor device.

It should be further noted that, in the embodiments of the present application, the material of the first isolation layer 15 may be silicon nitride. In other embodiments, the material of the first isolation layer 15 may also include silicon dioxide, silicon oxynitride, or a combination thereof, or a combination thereof with silicon nitride.

In some embodiments, step S102 may include the following steps.

A first initial isolation layer 13 is formed in the first trench 12.

During implementation, an isolation material may be deposited in the first trench 12 to form the first initial isolation layer 13 as shown in FIG. 8. For example, the first initial isolation layer 13 may be formed by depositing the isolation material through a process such as a chemical vapor deposition (chemical vapor deposition, CVD) process, a physical vapor deposition (physical vapor deposition, PVD) process, an atomic layer deposition (atomic layer deposition, ALD) process, a spin coating process, a coating process, or a thin film process. Here, the isolation material may be silicon nitride.

The first initial isolation layer 13 is etched back, and the retained part of the first initial isolation layer 13 located below the first insulating layer 202 and between first semiconductor layers 201 constitutes the first isolation layer 15, where the bottom surface of the first insulating layer 202 along the third direction extends beyond the top surface of the first isolation layer 15 along the third direction.

During implementation, first, a second photoresist layer 14 as shown in FIG. 9 is formed on the surface of the first initial isolation layer 13, and the second photoresist layer 14 and the first photoresist layer 11 have the same pattern; that is, the second photoresist layer 14 exposes the first initial isolation layer 13 in the first trench 12. Second, the first initial isolation layer 13 is etched to remove part of the first initial isolation layer 13 exposed by the second photoresist layer 14, and the remaining first initial isolation layer 13 located at the bottom of the first trench 12 constitutes the first isolation layer 15 as shown in FIG. 10. The bottom surface of the first insulating layer 202 in the Z-axis direction extends beyond the top surface of the first isolation layer 15 in the Z-axis direction.

It should be noted that, with continued reference to FIG. 10, in the process of etching back the first initial isolation layers 13, the first initial isolation layer 13 located on the top surface of each initial active strip 20b is not removed.

In some embodiments, the method for forming the semiconductor device may further include: forming a semiconductor isolation layer and/or a second insulating layer between the substrate 10 and the semiconductor layer 20.

It should be noted that the material of the second insulating layer may be silicon dioxide. The second insulating layer can reduce current leakage between the bit line structure and the substrate.

The semiconductor isolation layer may be an N-type doped layer or a P-type doped layer, and a reverse PN junction is formed between the semiconductor isolation layer and the semiconductor layer 20 (i.e., the first semiconductor layer 201), such that the current of the bit line structure cannot flow to the substrate 10. In this way, the current leakage between the bit line structure and the substrate 10 can be further reduced.

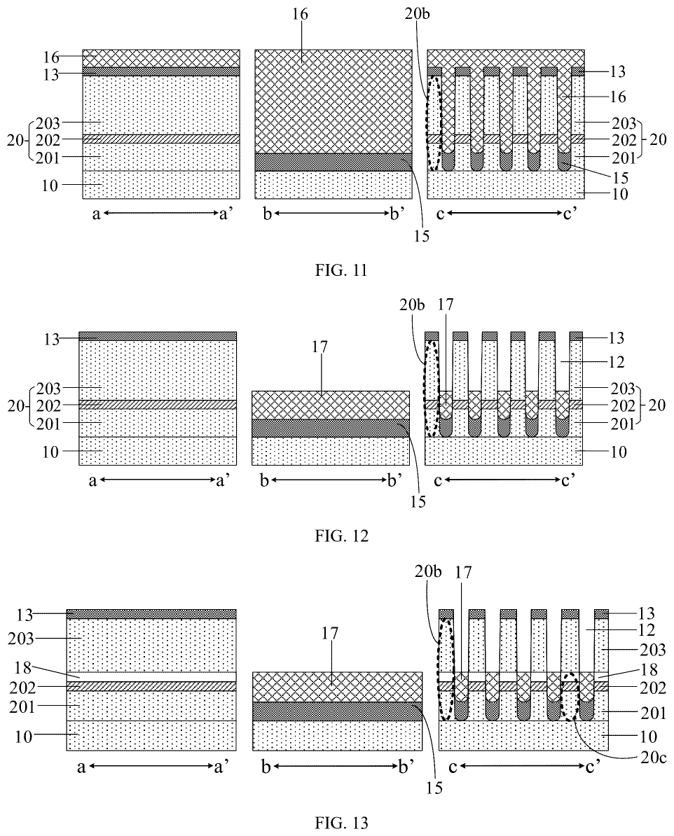

In some embodiments, referring to FIG. 11, the method for manufacturing the semiconductor device further includes:

A metal layer 17 is formed on the surface of the first isolation layer 15 in the first trench 12; the top surface of the metal layer 17 is located between second semiconductor layers 203.

During implementation, first, the metal material is deposited on the surfaces of the first isolation layer 15 and the retained first initial isolation layer 13 to form an initial metal layer 16 as shown in FIG. 11; second, the initial metal layer 16 is etched back, the initial metal layer 16 on the surface of the first initial isolation layer 13 is removed, and part of the initial metal layer 16 in the first trench 12 is removed to form the metal layer 17 as shown in FIG. 12. The metal material may be at least one of nickel, cobalt, or platinum.

Heat treatment is performed on the metal layer 17 and the second semiconductor layer 203 to form an ohmic contact layer 18 located at the bottom of the second semiconductor layer 203 as shown in FIG. 13.

It should be noted that the heat treatment process for the metal layer 17 and the second semiconductor layer 203 may be a rapid thermal processing (rapid thermal processing, RTP) process. During the rapid thermal processing process, metal ions in the metal layer 17 diffuse into the second semiconductor layer 203 around the metal layer, and undergo a silicide reaction with the second semiconductor layer 203 to form a metal silicide as the ohmic contact layer 18. Since a bit line structure is subsequently formed on the side wall of the ohmic contact layer 18 and in the first trench 12, and the metal silicide has a low resistance value, the contact resistance between the bit line structure and the second semiconductor layer 203 can be reduced, thereby reducing the power consumption of the formed semiconductor device.

It should be further noted that, usually, in the process of performing heat treatment on the metal layer 17 and the second semiconductor layer 203 to form a metal silicide, current leakage between a bit line structure and a bit line structure is easily induced, that is, a current leakage channel is easily formed between bit line structures. In the embodiments of the present application, since the first insulating layer 202 is formed at the bottom of the second semiconductor layer 203, the first insulating layer 202 can serve as a stop layer for metal ion doping, which can limit the position of metal ion doping in the second semiconductor layer 203, thereby preventing the formation of conductive paths (i.e., current leakage paths) between the bit line structures.

In addition, the position of the first insulating layer 202 can also control the thickness of the ohmic contact layer 18 in contact with the bit line structure. Due to the presence of the first insulating layer 202, the concentration and energy of the ohmic contact layer 18 (i.e., the metal silicide) are relatively not limited, which can better reduce the contact resistance with the bit line structure, thereby reducing the power consumption of the semiconductor device.

In some embodiments, the first semiconductor layer 201, the first insulating layer 202, and the ohmic contact layer 18 constitute an active strip 20c as shown in FIG. 13.

In some embodiments, after forming the ohmic contact layer 18, the method for forming the semiconductor device further includes: removing the metal layer 17. For example, the metal layer 17 may be etched and removed by a dry etching process.

Next, with continued reference to FIGS. 1, 15, and 16, step S103 is performed to form a bit line structure 19 on the top surface of the first isolation layer 15 and part of the inner wall of the first trench 12, where a gap is provided between two adjacent bit line structures 19 located in the same first trench 12.

It should be noted that forming the bit line structure 19 on the part of the inner wall of the first trench 12 means that the top surface of the bit line structure 19 is lower than the top surface of the initial active strip 20b, that is, the bit line structure 19 is formed at a position relatively close to the bottom in the first trench 12.

In some embodiments, step S103 may include the following steps.

An initial bit line structure 19a is formed on the inner wall of the first trench 12 and the surface of the first isolation layer 15.

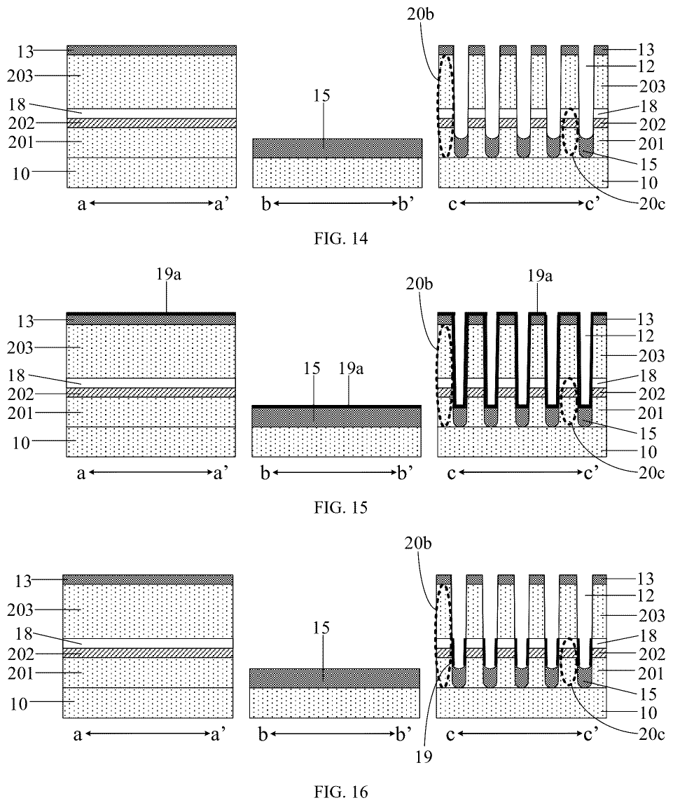

During implementation, a bit line material may be deposited on the first initial isolation layer 13, the inner wall of the first trench 12, and the top surface of the first isolation layer 15 as shown in FIG. 14 to form the initial bit line structure 19a as shown in FIG. 15. Here, the bit line material may be a single metal, a metal compound, or an alloy, where the single metal may be copper, aluminum, tungsten, gold, silver, or the like; the metal compound may be tantalum nitride or titanium nitride; the alloy may be an alloy material constituted by at least two of copper, aluminum, tungsten, gold, or silver.

The initial bit line structure 19a on the side wall of the second semiconductor layer 203 is removed, and the retained initial bit line structure 19a located on the first insulating layer 202, the ohmic contact layer 18, and the side wall of the first semiconductor layer 201 constitutes the bit line structure 19.

During implementation, part of the initial bit line structure 19a on the top surface of the first initial isolation layer 13 may be first removed by etching or a chemical mechanical polishing treatment process, and then part of the initial bit line structure 19a on the inner wall of the first trench 12 is removed by a dry etching technology. The retained initial bit line structure 19a located on the first insulating layer 202, the ohmic contact layer 18, and the side wall of the first semiconductor layer 201 not covered by the first isolation layer 15 constitutes the bit line structure 19 as shown in FIG. 16, that is, the bit line structure 19 covers the side wall of the active strip 20c.

Finally, with continued reference to FIGS. 1, 17, and 18, step S104 is performed to form a first isolation structure in the gap and an air gap located in the first isolation structure.

During implementation, a first isolation material is deposited between adjacent bit line structures 19 in the first trench 12. By controlling the deposition process, a first isolation structure 23 located between the adjacent bit line structures 19 in the first trench 12 and an air gap 22 located in the first isolation structure 23 are formed. Here, the first isolation material of the first isolation structure 23 may be silicon dioxide.

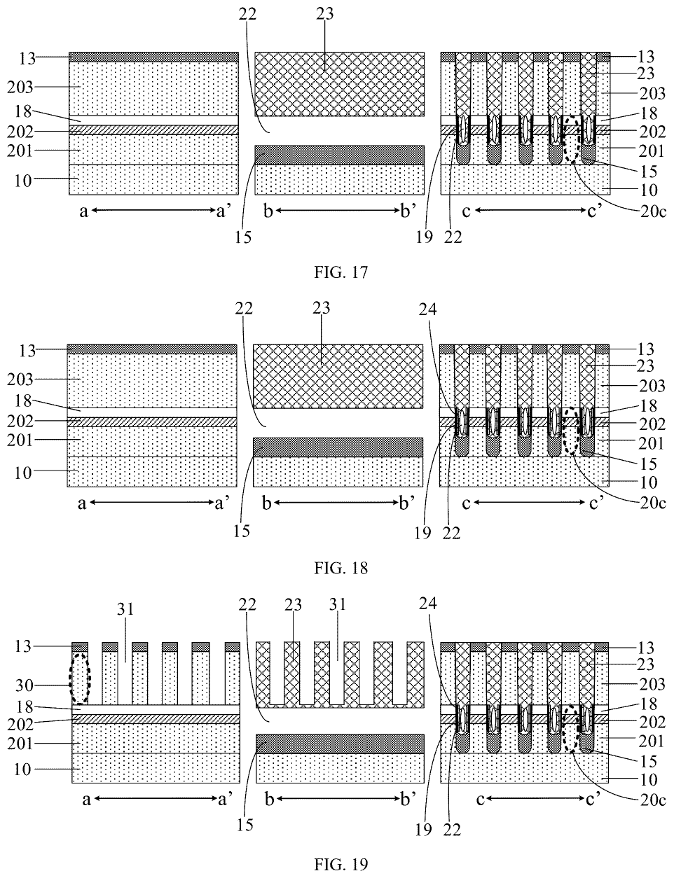

It should be noted that, with continued reference to FIG. 17, the first isolation structure 23 further fills the first trench 12.

In the embodiments of the present application, the air gap 22 can isolate the bit line structure 19, reduce the coupling effect between adjacent bit line structures 19, and reduce the parasitic capacitance, thereby improving the sensing margin of the sense amplifier.

In some embodiments, with continued reference to FIG. 18, before forming the first isolation structure 23 and the air gap 22, the method for manufacturing the semiconductor device further includes: forming a second isolation layer 24 on the surface of the bit line structure 19.

It should be noted that the material of the second isolation layer 24 includes a low-k dielectric material, i.e., a low-k material. The second isolation layer 24 may be formed by any suitable deposition process, such as ALD or CVD.

In the embodiments of the present application, the second isolation layer 24 formed using a low-k dielectric material can further reduce the parasitic capacitance between the bit line structures 19, thereby improving the sensing margin of the sense amplifier and the performance of the semiconductor device.

In some embodiments, referring to FIGS. 19 to 21, the method for manufacturing the semiconductor device further includes:
etching each first isolation structure 23 and the second semiconductor layer 203 to form a plurality of active pillars 30 arranged in an array along the first direction and the second direction, and second trenches 31 located between the plurality of active pillars 30 and extending along the second direction; each second trench 31 exposes the ohmic contact layer 18 and the first isolation structure 23.

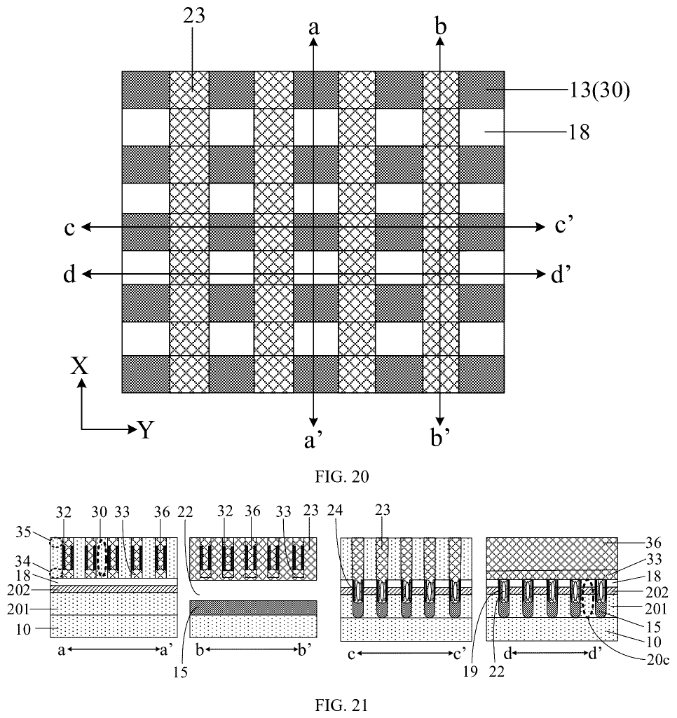

During implementation, a third photoresist layer (not shown) having a specific pattern is formed on the surfaces of the first isolation structure 23 and the second semiconductor layer 203, where the specific pattern includes a plurality of sub-patterns spaced apart from each other along the X-axis direction, and each sub-pattern extends along the Y-axis direction. The exposed first isolation structure 23 and the second semiconductor layer 203 are etched and removed through the third photoresist layer to form the active pillars 30 and the second trenches 31 extending along the Y-axis direction and spaced apart from each other along the X-axis direction as shown in FIGS. 19 and 20.

It should be noted that FIG. 20 is a top view of FIG. 19, and FIG. 21 is a cross-sectional view along a-a′, b-b′, c-c′, and d-d′ in FIG. 19.

A second isolation structure 33 is formed at the bottom of the second trench 31.

During implementation, a second isolation material is deposited at the bottom of the second trench 31 to form the second isolation structure 33 as shown in FIG. 21. The second isolation material may be silicon dioxide, silicon nitride, silicon oxynitride, or a combination thereof.

It should be noted that the second isolation structure 33 in the embodiments of the present application is used to isolate the adjacent bit line structure 19 and gate structure 32.

The gate structure 32 is formed on part of the side wall of the second trench 31 provided with the second isolation structures 33, where the top surface of each active pillar 30 extends beyond the top surface of the gate structure 32.

It should be noted that the gate structure 32 includes a gate dielectric layer and a gate conductive layer located on the surface of the gate dielectric layer. The material of the gate dielectric layer may be silicon oxide or another suitable material. The material of the gate conductive layer may be any one material with good conductive performance, for example, any one of titanium (Ti), titanium nitride (TiN), tungsten nitride (WN), tungsten (W), cobalt (Co), platinum (Pt), palladium (Pd), ruthenium (Ru), and copper (Cu). The gate dielectric layer and the gate conductive layer may be formed by any suitable deposition process, such as a chemical vapor deposition process, a physical vapor deposition process, or an atomic layer deposition process.

It should be further noted that the gate structure in the embodiments of the present application is a double-gate structure. In other embodiments, the gate structure may also be a gate-all-around structure or a single-gate structure.

It can be understood that the bottom and the top of the active pillar 30 not covered by the gate structure 32 constitute a first source/drain 34 and a second source/drain 35 of the semiconductor device, respectively, and the part of the active pillar 30 covered by the gate structure 32 constitutes a channel region of the semiconductor device. The first source/drain 34 is connected to the bit line structure 19 through the ohmic contact layer 18.

In some embodiments, after forming the gate structure 32, the method for forming the semiconductor device further includes:
depositing a second isolation material in the second trench 31 to form a third isolation structure 36, the third isolation structure 36 filling the second trench 31 and being flush with the top surface of the active pillar 30. The second isolation material may be silicon dioxide.

It should be noted that, in the embodiments of the present application, the third isolation structure 36 is used to isolate adjacent gate structures 32 to prevent current leakage or short circuit. In addition, the third isolation structure 36 fills the second trench 31, such that the semiconductor structure has a flat surface, which facilitates the subsequent formation of other functional structures.

In some embodiments, the method for forming the semiconductor device further includes: forming a capacitor structure connected to the second source/drain 35. It can be understood that the semiconductor device formed in the embodiments of the present application may be a DRAM.

In other embodiments, the formed semiconductor device may also be other memory devices or logic devices.

The semiconductor device in the embodiments of the present application is provided with a vertical channel, such that the dimension of the semiconductor device can be reduced, thereby achieving miniaturization. In addition, the control capability of the semiconductor device can also be improved, thereby improving the electrical performance of the semiconductor device.

According to the method for forming the semiconductor device according to the embodiments of the present application, since the first isolation layer is formed at the bottom of the bit line structure, the current leakage between the bit line structure and the base substrate can be prevented, thereby improving the electrical performance of the semiconductor device. In addition, since the air gap is formed between adjacent bit line structures, in this way, the coupling effect between adjacent bit line structures can be reduced, and the parasitic capacitance can be reduced, thereby improving the sensing margin of the sense amplifier, and further improving the performance of the formed semiconductor device.

Another embodiment of the present application provides a semiconductor structure as shown in the above-mentioned FIG. 21. As shown in FIG. 21, the semiconductor device includes:
a substrate 10;
active strips 20c and first trenches extending along the X-axis direction and alternately arranged along the Y-axis direction on the surface of the substrate 10, and a plurality of active pillars 30 located on the surfaces of the active strips 20c and spaced apart along the first direction;
a first isolation layer 15 extending along the X-axis direction and located at the bottom of each first trench;
a bit line structure 19 located on the top surface of the first isolation layer 15 and covering part of the side wall of one of the active strips 20c;
a first isolation structure 23 located between adjacent bit line structures 19 in the first trench; and
an air gap 22 located in the first isolation structure 23.

In some embodiments, the material of the first isolation layer 15 includes silicon nitride; the material of the first isolation structure 23 includes silicon dioxide.

In the embodiments of the present application, the first isolation layer 15 can prevent the current leakage from the bit line structure 19 to the substrate 10, thereby improving the electrical performance of the semiconductor device. In addition, the air gap in the first isolation structure 23 located between the bit line structures 19 can reduce the coupling effect between adjacent bit line structures 19 and reduce the parasitic capacitance, thereby improving the sensing margin of the sense amplifier, and further improving the performance of the semiconductor device.

In some embodiments, with continued reference to FIG. 21, the semiconductor device further includes: a second isolation layer 24 located between the bit line structure 19 and the first isolation structure 23.

It should be noted that the second isolation layer 24 can further reduce the parasitic capacitance between the bit line structures 19, thereby improving the sensing margin of the sense amplifier and the performance of the semiconductor device.

It should be noted that the material of the second isolation layer 24 includes a low-k dielectric material, i.e., a low-k material.

In some embodiments, with continued reference to FIG. 21, the active strip 20c includes a first semiconductor layer 201 located on the surface of the substrate 10, a first insulating layer 202, and an ohmic contact layer 18. The first isolation layer 15 is located in the first trench between first semiconductor layers 201, and the bottom surface of the first insulating layer 202 along the third direction extends beyond the top surface of the first isolation layer 15 along the third direction.

In some embodiments, the bit line structure 19 covering part of the side wall of the active strip 20c means that the bit line structure 19 covers the first insulating layer 202, the ohmic contact layer 18, and the side wall of the first semiconductor layer 201 not covered by the first isolation layer 15.

In some embodiments, with continued reference to FIG. 21, the semiconductor device further includes: second trenches located between the plurality of active pillars 30 and extending along the second direction; a second isolation structure 33 located at the bottom of each second trench; and a gate structure 32 located on the top surface of the second isolation structure 33 and covering part of the side wall of one of the active pillars 30, where the top surface of the active pillar 30 extends beyond the top surface of the gate structure 32.

In some embodiments, the gate structure 32 includes a gate dielectric layer and a gate conductive layer located on the surface of the gate dielectric layer. It should be further noted that the gate structure 32 in the embodiments of the present application is a double-gate structure. In other embodiments, the gate structure 32 may also be a gate-all-around structure or a single-gate structure.

The material of the second isolation structure 33 includes silicon dioxide.

In some embodiments, the bottom and the top of the active pillar 30 not covered by the gate structure 32 constitute a first source/drain 34 and a second source/drain 35 of the semiconductor device, respectively, and the part of the active pillar 30 covered by the gate structure 32 constitutes a channel region of the semiconductor device. The first source/drain 34 is connected to the bit line structure 19 through the ohmic contact layer 18.

In some embodiments, with continued reference to FIG. 21, the semiconductor device further includes: a third isolation structure 36; the third isolation structure 36 is located between gate structures 32 and fills the second trench, and the third isolation structure 36 is flush with the top surface of the active pillar 30.

The material of the third isolation structure 36 includes silicon dioxide.

In some embodiments, the semiconductor device further includes a capacitor structure (not shown); the capacitor structure is connected to the second source/drain 35.

It can be understood that the semiconductor device in the embodiments of the present application may be a DRAM. In other embodiments, the semiconductor device may also be another type of memory, for example, a NAND flash memory or a phase-change memory.

It should be noted that the semiconductor device formed in the embodiments of the present application is similar to the semiconductor device in the above embodiments. For technical features not disclosed in detail in the embodiments of the present application, reference can be made to the above embodiments for understanding, and details are not described here again.

The semiconductor device according to the embodiments of the present application includes the first isolation layer, and the first isolation layer is located at the bottom of the bit line structure. Therefore, the current leakage between the bit line structure and the substrate can be prevented, thereby improving the electrical performance of the semiconductor device.

In addition, since the semiconductor device includes the air gap, and the air gap is located in the first isolation structure between the bit line structures, the coupling effect between adjacent bit line structures can be reduced, and the parasitic capacitance can be reduced, thereby improving the sensing margin of the sense amplifier.

In the embodiments provided in the present application, it should be understood that the disclosed structure and method may be implemented in a non-targeted manner. The structural embodiments described above are merely illustrative. For example, the division into the units is only a logical functional division, and in actual implementation, there may be other division manners. For example, a plurality of units or modules may be combined, or may be integrated into another system; or some features may be ignored or not implemented. In addition, the various components shown or discussed are coupled or directly coupled to each other.

The features disclosed in the method or structural embodiments provided in the present application may be combined in any manner if without conflict to obtain new method embodiments or structural embodiments.

The foregoing descriptions are only some embodiments of the present application, but the protection scope of the present application is not limited thereto. Changes or substitutions that any one skilled in the art can easily think of within the technical scope disclosed by the present application shall all fall within the protection scope of the present application. Therefore, the protection scope of the present application shall be defined by the protection scope of the claims.

What is claimed is:

1. A semiconductor device, comprising:
a substrate;
active strips and first trenches located on a surface of the substrate, extending along a first direction, and alternately arranged along a second direction, and a plurality of active pillars located on surfaces of the active strips and spaced apart along the first direction;
a first isolation layer extending along the first direction and located at a bottom of each of the first trenches;
a bit line structure located on a top surface of the first isolation layer and covering part of a side wall of one of the active strips;
a first isolation structure located between adjacent bit line structures in the first trench; and
an air gap located in the first isolation structure, wherein
the first direction intersects with the second direction and is located in a plane where the substrate is located.

2. The semiconductor device according to claim 1, further comprising:
a second isolation layer located between the bit line structures and the first isolation structure.

3. The semiconductor device according to claim 1, wherein the active strip comprises a first semiconductor layer located on the surface of the substrate, a first insulating layer, and an ohmic contact layer;
the first isolation layer is located in the first trench between first semiconductor layers, a bottom surface of the first insulating layer along a third direction extends beyond a top surface of the first isolation layer along the third direction; the third direction intersects with the plane where the substrate is located;
the bit line structure covers the first insulating layer, the ohmic contact layer, and part of a side wall of the first semiconductor layer not covered by the first isolation layer.

4. The semiconductor device according to claim 3, further comprising: second trenches located between the plurality of active pillars and extending along the second direction;
a second isolation structure located at a bottom of each of the second trenches; and
a gate structure located on a top surface of the second isolation structure and covering part of a side wall of one of the active pillars, wherein a top surface of the active pillar extends beyond a top surface of the gate structure.

5. The semiconductor device according to claim 4, wherein the gate structure is a single-gate structure, a double-gate structure, or a gate-all-around structure.

6. The semiconductor device according to claim 4, further comprising: a third isolation structure, wherein the third isolation structure is located between gate structures and fills the second trench.

7. The semiconductor device according to claim 6, wherein the third isolation structure is flush with the top surface of the active pillar.

8. The semiconductor device according to claim 6, wherein a material of the third isolation structure comprises silicon dioxide.

9. The semiconductor device according to claim 2, wherein
a material of the first isolation layer comprises silicon nitride;
a material of the second isolation layer comprises a low-k dielectric material;
a material of the first isolation structure comprises silicon dioxide.

10. A method for manufacturing a semiconductor device, comprising:
providing a base substrate, wherein the base substrate comprises initial active strips and first trenches extending along a first direction and alternately arranged along a second direction;
forming a first isolation layer extending along the first direction at a bottom of each of the first trenches;
forming a bit line structure on a top surface of the first isolation layer and part of an inner wall of the first trench, wherein a gap is provided between two adjacent bit line structures located in a same first trench; and
forming a first isolation structure in the gap and an air gap located in the first isolation structure, wherein
the first direction intersects with the second direction and is located in a plane where the base substrate is located.

11. The method according to claim 10, wherein before forming the first isolation structure and the air gap, the method further comprises:
forming a second isolation layer on a surface of the bit line structure.

12. The method according to claim 10, wherein providing the base substrate comprises:
providing a substrate and a semiconductor layer, wherein the semiconductor layer comprises a first semiconductor layer, a first insulating layer, and a second semiconductor layer sequentially stacked along a third direction; the third direction intersects with the plane where the base substrate is located; and
patterning the semiconductor layer until the substrate is exposed to form the initial active strips and the first trenches, wherein each of the initial active strips comprises the first semiconductor layer, the first insulating layer, and the second semiconductor layer sequentially stacked along the third direction.

13. The method according to claim 12, wherein providing the semiconductor layer comprises:
providing an initial semiconductor structure;
performing oxygen ion implantation on the initial semiconductor structure to form a buried layer located inside the initial semiconductor structure; and
annealing the initial semiconductor structure and the buried layer to form the first insulating layer, wherein a material of the first insulating layer comprises silicon dioxide, the initial semiconductor structure located below the first insulating layer constitutes the first semiconductor layer, and the initial semiconductor structure located above the first insulating layer constitutes the second semiconductor layer.

14. The method according to claim 12, wherein forming the first isolation layer extending along the first direction at the bottom of each of the first trenches comprises:
forming a first initial isolation layer in the first trench; and
etching back the first initial isolation layer, a retained part of the first initial isolation layer located below the first insulating layer and between first semiconductor layers constituting the first isolation layer, wherein a bottom surface of the first insulating layer along the third direction extends beyond the top surface of the first isolation layer along the third direction.

15. The method according to claim 12, wherein before forming the bit line structure, the method further comprises:
forming a metal layer on a surface of the first isolation layer in the first trench, wherein a top surface of the metal layer is located between second semiconductor layers; and
performing heat treatment on the metal layer and the second semiconductor layer to form an ohmic contact layer located at a bottom of the second semiconductor layer, wherein
the first semiconductor layer, the first insulating layer, and the ohmic contact layer constitute an active strip, and the bit line structure covers part of a side wall of the active strip.

16. The method according to claim 15, wherein forming the bit line structure on the top surface of the first isolation layer and part of the inner wall of the first trench comprises:
forming an initial bit line structure on the inner wall of the first trench and the surface of the first isolation layer; and
removing the initial bit line structure on a side wall of the second semiconductor layer, the retained initial bit line structure located on the first insulating layer, the ohmic contact layer, and a side wall of the first semiconductor layer constituting the bit line structure.

17. The method according to claim 15, wherein the first isolation structure further fills the first trench; the method further comprises:
etching the first isolation structure and the second semiconductor layer to form a plurality of active pillars arranged in an array along the first direction and the second direction, and second trenches located between the plurality of active pillars and extending along the second direction, wherein each of the second trenches exposes the ohmic contact layer and the first isolation structure;
forming a second isolation structure at a bottom of the second trench; and
forming a gate structure on part of a side wall of the second trench provided with the second isolation structure, wherein a top surface of each of the plurality of the active pillars extends beyond a top surface of the gate structure.

18. The method according to claim 11, wherein
a material of the first isolation layer comprises silicon nitride;
a material of the second isolation layer comprises a low-k dielectric material;
a material of the first isolation structure comprises silicon dioxide.

19. The method according to claim 12, further comprising:
forming a semiconductor isolation layer or a second insulating layer between the substrate and the semiconductor layer.

20. The method according to claim 19, wherein the semiconductor isolation layer is an N-type doped layer or a P-type doped layer, and the semiconductor isolation layer forms a reverse PN junction between the semiconductor layers.
